(19) United States
(12) Patent Application Publication
(10) Pub. No.: US 2010/0027219 A1
(43) Pub. Date: Feb. 4, 2010

(54) FAN FRAME ASSEMBLY FOR A HEAT SINK

(75) Inventor: CHIEN-YEN LU, Kaohsiung (TW)

Correspondence Address: G. LINK CO., LTD., 3550 BELL ROAD, MINOOKA, IL, 60447, US

(73) Assignee: ASIA VITAL COMPONENTS CO., LTD., Kaohsiung (TW)

(21) Appl. No.: 12/183,235

(22) Filed: Jul. 31, 2008

(51) Int. Cl. H05K 7/20

(52) U.S. Cl. 361/697

(57) ABSTRACT

A fan frame assembly for a heat sink includes the fan frame, the fasteners and the heat sink. The fan frame has the plate-shaped holding members extending downward along the circumferential side thereof with a horizontal engaging end part respectively. The engaging end part has a piercing hole for being passed through by the respective fasteners. Due to the fasteners being surrounded with a spring, the spring exerts a pressing force to the fan frame in addition to the holding members locating the heat sink for the fan frame assembly being joined to the heat sink firmly.

### BACKGROUND OF THE INVENTION

1. Field of the Invention

The present invention is related to a heat dissipation fan for a heat sink and particularly to a fan frame assembly, which provides a structure with direct pressing force and decrease of the production cost.

2. Brief Description of the Related Art

The central processing unit (CPU) is the most important component of a computer. The operation speed and the efficiency of the CPU are enhanced tremendously due to the incessant development of the computer technology and the promotion of the production efficiency for the integrated circuit. However, the high operation speed of the CPU results in generation of the highly increasing heat, which affects stability of the running computer. In order to solve the problem of overheating, a heat dissipation device is adapted to the CPU to guide the heat source outward the CPU and to stabilize the operation of the CPU.

The conventional heat dissipation device as shown in FIGS. 4, 4A and 4B has a fan E, a connecting member F and a heat sink G. The upper edge of the connecting member F provides a plurality of locating hooks F1 and the lower edge of the connecting member F has a plurality of engaging hooks F2. The upper side of the heat sink G has an elongated groove G1. While assembling the heat dissipation device, the connecting member F engages with the fan E by means of the locating hooks F1 and engages with the elongated groove G1 by means of the engaging hooks F2 such that a heat dissipation module can be set up.

In order to join the conventional heat dissipation device to the fan, an additional connecting member has to be employed further. However, the additional connecting member results in increase of labor time and labor cost.

### SUMMARY OF THE INVENTION

The main object of the present invention is to provide a fan frame assembly for a heat sink without the additional connecting member and the additional production cost.

Another object of the present invention is to provide a fan frame assembly for a heat sink with a structure capable of producing the direct pressing force.

Accordingly, a fan frame assembly for a heat sink according to the present invention includes a fan frame, a plurality of fasteners and a heat sink, wherein the fan frame has the plate-shaped holding members extending downward along the circumferential side thereof with a horizontal engaging end part respectively; the engaging end part has a piercing hole for being passed through by the respective fasteners; due to the fasteners being surrounded with a spring, the spring exerts a pressing force to the fan frame in addition to the holding members locating the heat sink such that the fan frame assembly is joined to the heat sink firmly.

### BRIEF DESCRIPTION OF THE DRAWINGS

The detail structure, the applied principle, the function and the effectiveness of the present invention can be more fully understood with reference to the following description and accompanying drawings, in which:

FIG. 1 is a perspective view of a fan frame assembly for a heat sink according to the present invention;

FIG. 2 is a disassembling perspective view of the fan frame assembly for a heat sink shown in FIG. 1;

FIG. 3 is a sectional view of the fan frame assembly for a heat sink shown in FIG. 1;

FIG. 4 is a perspective view of the conventional assembly of fan and the heat sink; and

FIGS. 4A and 4B are enlarged perspective views of the two dash line circles shown in FIG. 4.

### DETAILED DESCRIPTION OF THE INVENTION

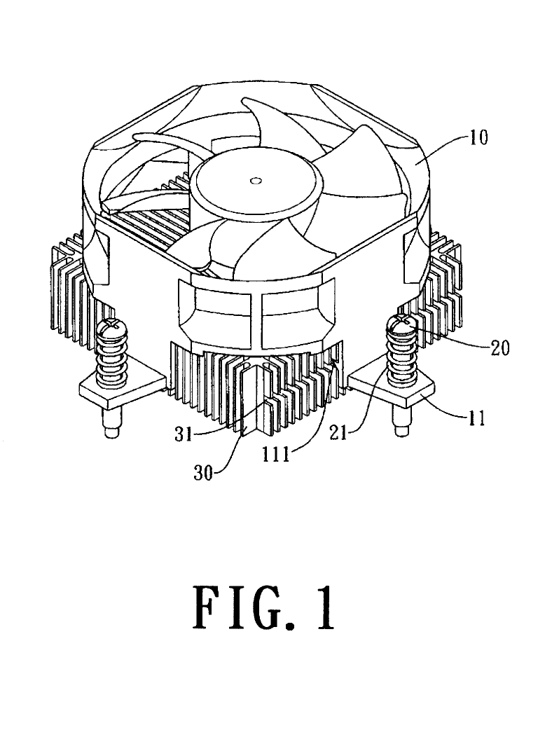

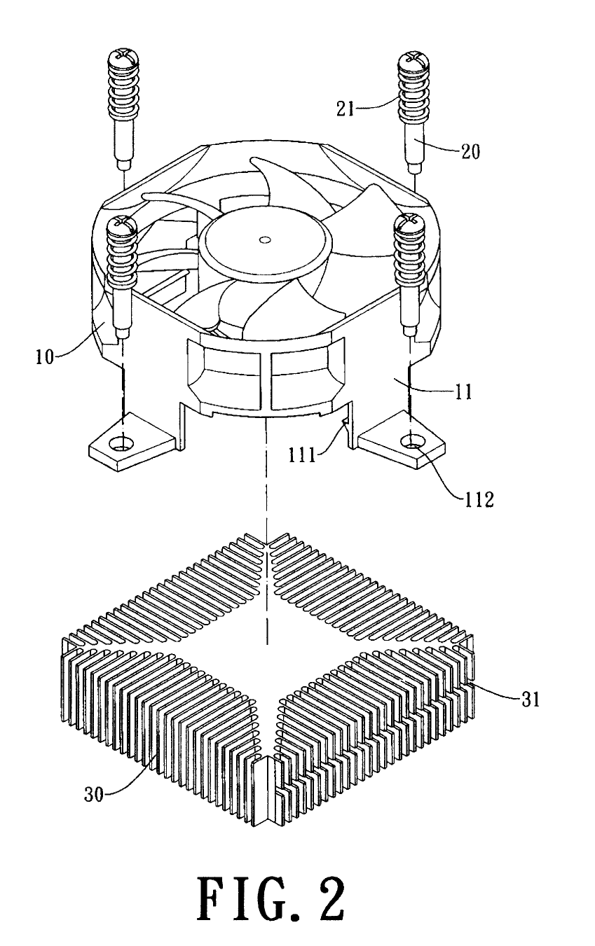

Referring to FIGS. 1 and 2, the first embodiment of a fan frame assembly for a heat sink according to the present invention includes a fan frame 10, a plurality of engaging members 20 and a heat sink 30. The fan frame 10 provides a plurality of plate-shaped holding members 11 extending from the circumferential side thereof to embrace the heat sink 30. Each of the holding members 11 has an engaging end plate at the outer side thereof such that the main body of the respective holding member 11 and the engaging end constitute a shape of “L” shape. Further, an engaging hole 112 pierces the engaging end and an inverted hook 111 is provided at the inner side of the respective holding member 11 opposite to the engaging end. There are four holding members 11 spacing apart from each other shown in FIGS. 1 and 2.

A bolt shaped fastener 20 is provided to correspond to the engaging hole 112 respectively with a coil spring 21 surrounding the fastener 20.

The heat sink 30 is disposed next to the fan frame 10 and has a square shape with a transverse groove extending along the outer side the heat sink 30 corresponding to the inverted hook 111.

When the fan assembly is set up, the fastener 20 passes through the engaging hole 112 and the fan frame 10 is placed next to the heat sink 30. Further, the fastener 20 engages with a base (not shown) such that the spring 21 presses the fan frame 10 directly to allow the inverted hook 111 to engage with the transverse groove 31. Under this circumference, the fan frame 10 can hold and locate the heat sink 30 firmly.

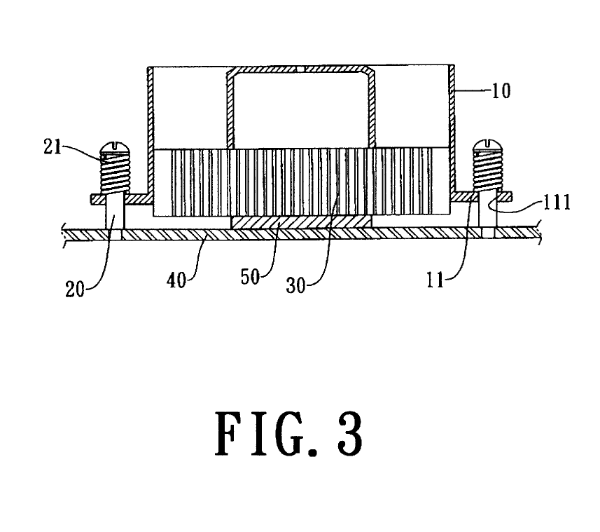

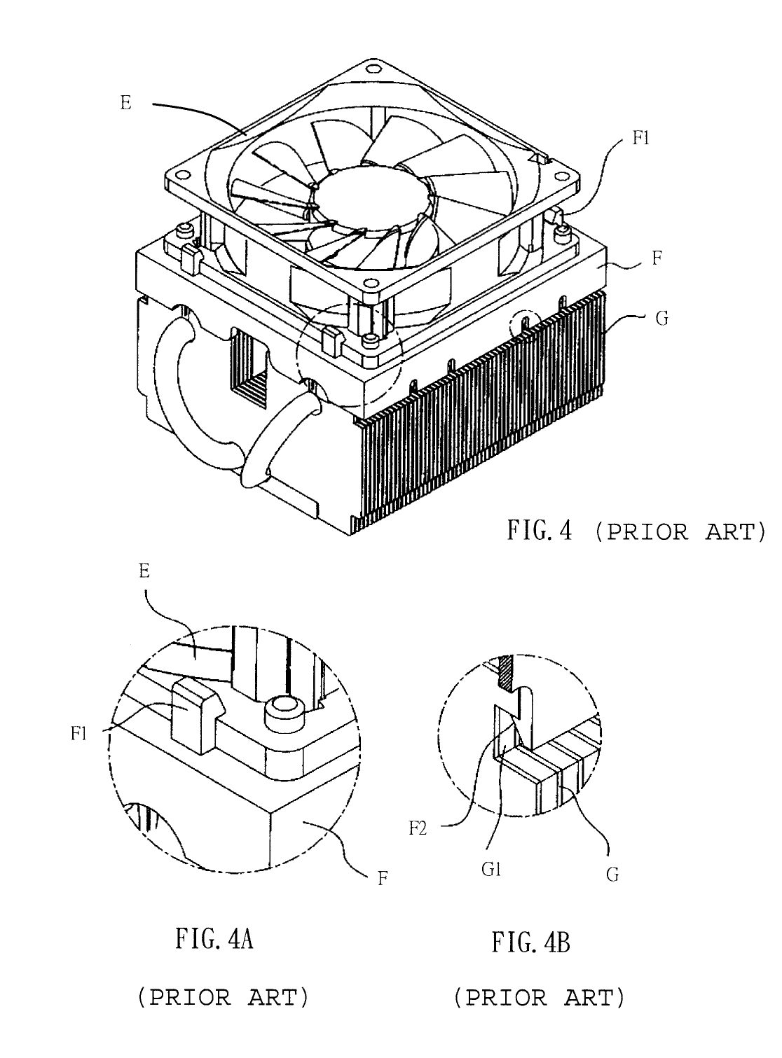

Referring to FIG. 3, in case of the fan assembly with the heat sink being employed to cool the CPU 50 of a mother board 40 of a computer, the heat sink 30 is placed to the CPU 50 and then the fan frame 10 is placed on the heat sink 30 before the engaging member 20 passes through the engaging hole 111 of the respective holding member 11 such that the mother board 40 can be joined to the heat sink 30. In this way, the fan frame 10, the heat sink 30, the CPU 30 and the mother board 40 are capable of being assembled together as a single unit.

While the invention has been described with referencing to the preferred embodiment thereof, it is to be understood that modifications or variations may be easily made without departing from the spirit of this invention, which is defined by the appended claims.

1. A fan frame assembly for a heat sink comprising:
a fan frame;
a heat sink being disposed next to said fan frame; and
a plurality of bolt-shaped fasteners to join said fan frame to the said heat sink;
wherein, a plurality of plate-shaped holding members are provided at the circumferential side of said fan frame with an end part having an engaging through hole extending outward from the bottom of said holding members respectively to form an “L” shape and each of said fasteners is surrounded with a spring for the respective fastener passing through said engaging hole, and an inverted hook is provided on the respective holding member opposite to said end part, and a transverse grove is provided along the outer surface of said heat sink corresponding to said inverted hook for said inverted hook engaging with said transverse groove such that said fasteners engage with a mother board in a way of a space being formed between said end part and said mother board and said space being greater than a gap, which accommodates a central processing unit (CPU), between said heat sink and said mother board.

2-3. (canceled)
